(19) United States
(12) Patent Application Publication
(10) Pub. No.: US 2002/0079539 A1
(43) Pub. Date: Jun. 27, 2002

(54) Method for fabricating an I/O pad with improved ESD tolerance

(76) Inventors: Te-Wei Chen, Hsinchu Hsien (TW); Huang-Hui Liu, Taipei Hsien (TW)

Correspondence Address: J.C. Patents, Inc., 4 VENTURE, SUITE 250, Irvine, CA, 92618, US

(21) Appl. No.: 09/746,805

(22) Filed: Dec. 22, 2000

(51) Int. Cl. H01L 23/62

(52) U.S. Cl. 257/355

(57) ABSTRACT

The invention provides a method for improved ESD protection for an I/O pad by utilizing a zener diode. An n-well is formed in a provided semiconductor substrate. After which, a gate structure is formed on the n-well in the semiconductor substrate. Subsequently, a first p-type region and a second p-type region are formed adjacent to the gate structure. Then an n-type region is formed in the n-well. The first p-type region is operatively connected to the I/O pad and the second p-type region is connected to a power supply voltage. A zener diode is operatively connected between the n-type region and the power supply voltage. More particularly, the anode of the zener diode is connected to Vcc and the cathode of the zener diode is connected to the n-type region. The zener diode breakdown voltage must be correctly selected in order to provide adequate ESD protection and at the same time ensure that the I/O circuitry can operate correctly during normal operation without being adversely affected by the zener diode.

### BACKGROUND OF THE INVENTION

1. Field of Invention

The present invention relates to ESD protection, and more particularly, to a method for improving the tolerance to ESD for an I/O pad by utilizing a zener diode.

2. Description of Related Art

Electrostatic discharge (ESD) can occur when an electrostatic charge accumulates. This can occur whenever semiconductor devices are handled or for various other reasons. This electrostatic charge can potentially result in the destruction or at the very least damage to the device. Destruction of the device is usually very noticable, as the device becomes inoperable. However, if the device is damaged, the damage may not be immediately noticable but could disable some functions or shorten the lifetime of the device.

Input/Output (I/O) pads are particularly vulnerable to ESD, which can damage or destroy internal circuitry connected to the I/O pad. Therefore, ESD protection circuits have been developed to protect circuitry from this hazard.

A consideration for ESD protection circuit design is to ensure that the voltage required to activate the protection circuit is lower than the dielectric breakdown voltage of the gate oxide layers of the MOS device. In this way, the ESD protection circuit can provide protection to the device. Another design consideration is that the ESD protection circuit provides protection to the device without getting damaged itself.

Refer to FIG. 1, which is a schematic diagram showing a conventional I/O pad structure. The I/O pad 10 as shown in FIG. 1 is connected to drive a gate. Notice the presence of a floating n-well 20. It can be seen that if a high voltage is accidentally applied to the I/O pad 10, the discharge can cause gate oxide breakdown of the devices to which it is applied. This is due to the fact that there is no current path for the ESD current. Therefore, the devices will breakdown due to the stress caused by the ESD event. This breakdown can cause immediate destruction of the device or it may weaken the oxide enough such that failure may occur early in the life of the device. Therefore, it is advantageous for I/O pads to be provided with protective circuits to prevent voltages from damaging devices.

These protective circuits can be situated between the I/O pads and the gates to which the pads are connected. They are designed to provide an electrical path to ground when excess voltage occurs. These protection devices are design to dissipate the excess voltage before the voltage on the I/O pad can reach a level that would damage the internal devices connected to the I/O pad.

A conventional approach to ESD protection circuits is to use a two-stage protection circuit on circuit inputs. In this type of design, when a high current ESD pulse passes through the first stage, the circuit clamps the pad voltage. However, this can allow voltage that is still too high for the internal circuitry. Therefore, a second stage is required to clamp the voltage to a safe value.

As semiconductor technology has improved, shorter transistor channel lengths and smaller device sizes have made it increasingly difficult to protect input and output circuitry from ESD. As the device size decreases, the breakdown voltage for the device will also decrease. Therefore, the conventional approach to ESD protection is not suitable, as it will no longer adequately protect internal circuitry as the devices will fail before the ESD protection circuit begins clamping the ESD pulse.

### SUMMARY OF THE INVENTION

Therefore, in order to overcome the shortcomings and disadvantages of conventional designs, the invention provides a method for improved ESD protection for an I/O pad utilizing a zener diode.

An n-well is formed in a provided semiconductor substrate. After which, a gate structure is formed on the n-well in the semiconductor substrate. Subsequently, a first p-type region and a second p-type region are formed adjacent to the gate structure. Then an n-type region is formed in the n-well. The first p-type region is operatively connected to the I/O pad and the second p-type region is connected to a power supply voltage. A zener diode is operatively connected between the n-type region and the power supply voltage, with the anode of the diode connected to Vcc and the cathode of the diode connected to the n-type region. The zener diode breakdown voltage must be correctly selected in order to provide adequate ESD protection and at the same time ensure that the I/O circuitry can operate correctly during normal operation without being adversely affected by the zener diode protection circuit.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram showing a conventional I/O pad;

FIG. 2 is a schematic diagram showing an I/O pad with improved ESD tolerance according to an embodiment of the present invention; and

FIG. 3 is a cross-section showing an I/O pad with improved ESD tolerance according to an embodiment of the present invention.

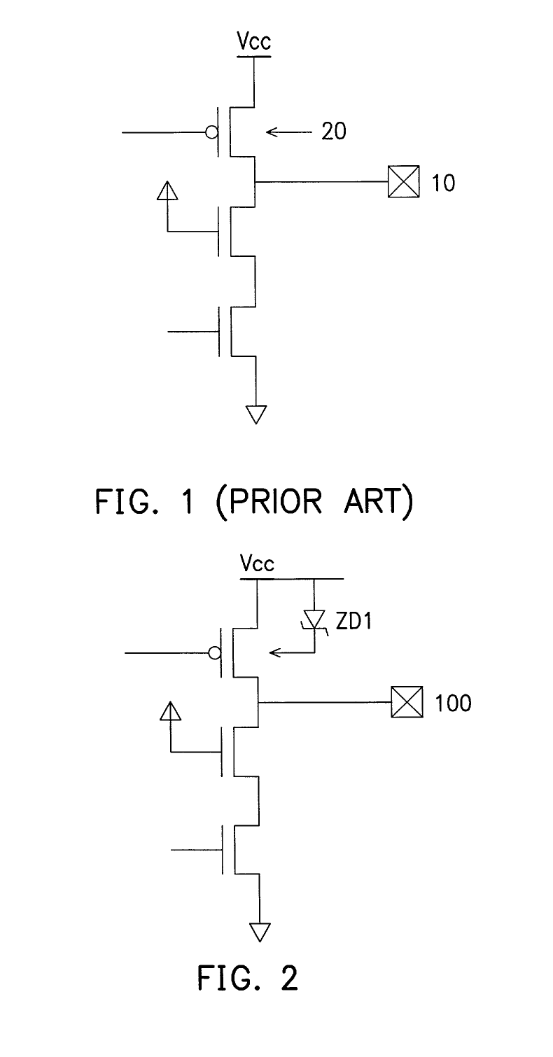

### DESCRIPTION OF THE PREFERRED EMBODIMIENTS

In order to overcome the shortcomings and disadvantages of the conventional design, the invention provides a method for improved ESD protection for an I/O pad by utilizing a zener diode.

Refer to FIG. 2, which is a schematic diagram showing an I/O pad with improved ESD tolerance according to an embodiment of the present invention.

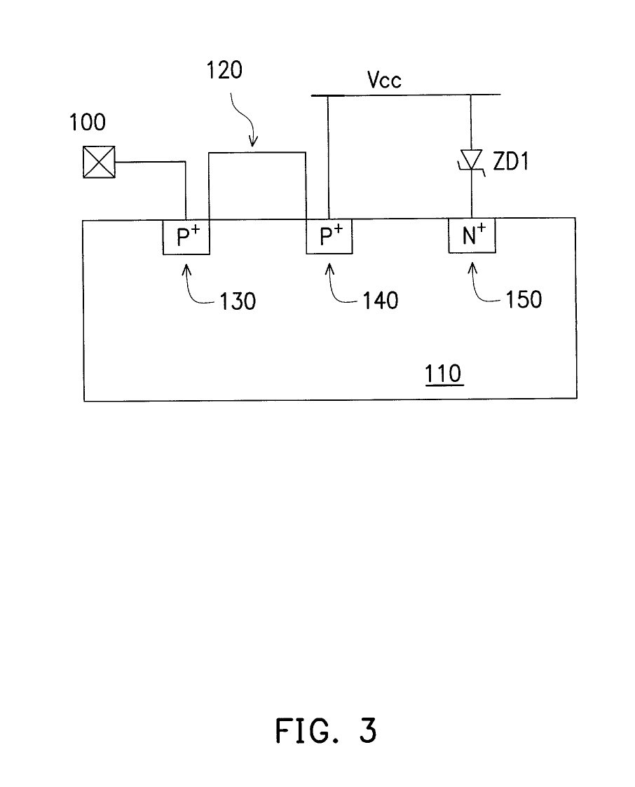

Also, refer to FIG. 3, which is a gate level diagram showing an I/O pad with improved ESD tolerance according to an embodiment of the present invention.

An n-well 110 is formed in a provided semiconductor substrate (not shown). After which, a gate structure 120 is formed on the n-well 110 in the semiconductor substrate. Subsequently, a first p-type region 130 and a second p-type region 140 are formed adjacent to the gate structure 120. Then an n-type region 150 is formed in the n-well 110. The first p-type region 130 is operatively connected to the I/O pad 100 and the second p-type region 140 is connected to the power supply voltage Vcc.

A zener diode ZD1 is operatively connected between the n-type region 150 and the power supply voltage Vcc. More particularly, the anode of the zener diode ZD1 is connected to Vcc and the cathode of the zener diode ZD1 is connected to the n-type region 150.

The zener diode ZD1 is provided to break down when an excess voltage is present on the I/O pad 100. For example, during an ESD event as soon as the voltage exceeds the zener diode ZD1 breakdown voltage, zener diode ZD1 breakdown occurs and a current path is provided for the ESD current. Therefore, internal circuitry connected to the I/O pad 100 is protected from damage caused by ESD events.

Basically, there are two requirements for the zener diode of the ESD protection circuit of the present invention. Note that these requirements are for standard semiconductor technology processes but can be easily modified to adapt to various adaptations or changes in semiconductor technology. One requirement is that the zener breakdown voltage should not be greater than the MOS breakdown voltage. This is to ensure that when an ESD pulse occurs, the zener diode breakdown voltage is less than or equal to the MOS breakdown voltage. Typically, MOS breakdown voltage is about 6 volts. If the zener diode breakdown voltage is greater than the MOS breakdown voltage, the MOS would be damaged before the zener diode would breakdown and provide protection. The other requirement is that the I/O pad can operate normally without the zener diode protection circuit adversely affecting the signal. Therefore, Vcc plus the zener diode breakdown voltage should be less than or equal to about 9.3 volts and greater than or equal to 5.5 volts. For example, using a standard Vcc of about 3.3 volts, the desired zener breakdown voltage would be from about 2.2 volts to about 6 volts. This will ensure that the I/O pad during normal operation can accept a valid logic voltage level and function correctly without the zener diode affecting the signal.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An improved ESD tolerant I/O pad comprising:
providing a semiconductor substrate;
forming an n-well in the semiconductor substrate;
forming a gate structure on the n-well in the semiconductor substrate;
forming a first p-type region and a second p-type region adjacent to the gate structure;
forming an n-type region in the n-well;
connecting the first p-type region to the I/O pad;
connecting the second p-type region to a power supply; and
connecting a zener diode between the n-type region and a power supply, wherein the zener diode has an anode and a cathode and wherein the anode is connected to the power supply and the cathode is connected to the n-type region.

2. The improved ESD tolerant I/O pad of claim 1, wherein a breakdown voltage of the zener diode is about 3.5 volts.

3. The improved ESD tolerant I/O pad of claim 1, wherein conductivity types of n-type and p-type and electrical polarities of the anode and cathode are interchanged.

4. An improved ESD tolerant I/O pad comprising:
an n-well formed in a substrate;
a p-type region and an n-type region formed in the n-well, wherein the p-type region is connected to the I/O pad; and
a zener diode comprising an anode and a cathode, wherein the anode is connected to a power supply and the cathode is connected to the n-type region.

5. The improved ESD tolerant I/O pad of claim 4, wherein a breakdown voltage of the zener diode is about 3.5 volts.

6. The improved ESD tolerant I/O pad of claim 4, wherein conductivity types of n-type and p-type and electrical polarities of the anode and cathode are interchanged.
